(19) United States
(12) Patent Application Publication
(10) Pub. No.: US 2003/0087026 A1
(43) Pub. Date: May 8, 2003

(54) Multi-nozzle printing method for PLED displays

(76) Inventors: Johan Frederik Dijksman, Eindhoven (NL); Johannes Adrianus De Wit, Eindhoven (NL); Henk Albert Hessel, Eindhoven (NL); Martin Maurice Vernhout, Eindhoven (NL); Paulus Cornelis Duineveld, Eindhoven (NL)

Correspondence Address: U.S. Philips Corporation, 580 White Plains Road, Tarrytown, NY, 10591, US

(21) Appl. No.: 10/270,982

(22) Filed: Oct. 15, 2002

(30) Foreign Application Priority Data
Oct. 19, 2001 (EP) 01204000.2

(51) Int. Cl. B05D 5/12; B05D 1/36

(52) U.S. Cl. 427/58; 427/258

(57) ABSTRACT

The present invention relates to a method and an apparatus for forming light-emitting diodes (LEDs) on a substrate, and more specifically for producing LED display screens. The method comprises the steps of: simultaneously depositing a plurality of dots on the substrate to form light-emitting pixels of the same color; and repeating said depositing step in at least one displaced position on the substrate.

The present invention relates to a method and an apparatus for forming light-emitting diodes (LEDs) on a substrate, and more specifically for producing LED display screens.

Recently, there has been increased interest in substrates provided with light-emitting diodes, e.g. made from organic polymers, because of their potential low cost and potential applicability in small and large color flat panel displays. The LED materials could be deposited by spin-coating or by evaporation. Different colors are obtained in light-emitting diodes by placing red, green and blue emitting materials in proximity to each other.

Recently, it has further been proposed to use an ink-jet method for depositing LED material on a substrate. This is known from e.g. U.S. Pat. No. 6,087,196, EP 0 880 303 and U.S. Pat. No. 6,013,982. U.S. Pat. No. 6,087,196 further discloses the use of multiple nozzles for deposition of different substances on the substrate, in order to provide LEDs of different colors. However, a problem with these known methods is that they are relatively expensive and time-consuming.

It is therefore an object of the present invention to provide a more efficient method and apparatus for forming light-emitting diodes on a substrate.

In the context of this application the following definitions apply:

Droplet: droplet of a LED-forming material produced on demand by a print head.

Dot: circular space occupied by a droplet after landing and spreading on a substrate.

Dot placement error: deviation from a prescribed position of the centre of a dot.

Pixel: light-emitting basic element of a substrate with LEDs formed thereon, such as a display. For monochrome displays, the dimensions are about 200-300 by 200-300 μm², for color displays, the dimensions are 60 by 200 μm². A pixel may be built up of several dots.

Pixel pitch: The distance between pixels of similar type formed on a substrate. For monochrome displays, this is the distance between the centers of adjacent pixels. For color displays, it denotes the distance between pixels of the same color. The pixel pitch of the LED-displays is 200-300 μm. The vertical pixel pitch may be different from the horizontal pixel pitch.

Dot pitch: the distance between the centers of adjacent dots. As a pixel can be composed of different dots, the dot pitch is not necessarily the same as the pixel pitch. Again the horizontal dot pitch may be different from the vertical dot pitch.

DPI: dots per inch, which is a standard measure in the graphics industry.

A method according to the invention for forming a plurality of light-emitting diodes on a substrate comprises the steps of: simultaneously depositing a plurality of dots on the substrate to form light-emitting pixels of the same color; and repeating said depositing step in at least one displaced position on the substrate. Preferably, at least five dots are deposited simultaneously on the substrate, preferably at least 10, and most preferably at least 100.

By depositing several dots simultaneously, the efficiency and manufacturing speed could be improved radically. If enough dots are deposited simultaneously, an entire display could be printed in one run by printing a number of parallel lines at the same time. The pitch of the lines can be adjusted by mounting the printing head at an angle. Furthermore, the invention could increase the redundancy, and thus the quality of the manufacturing process as well as the products. Especially, the inventive method could be used for averaging out differences between the individual nozzles when the lines and the like are built up of droplets coming from all the nozzles. Moreover, the invention provides a flexible method that could be used for printing of several different types and sizes of substrates.

The deposition is preferably performed by a controlled discharge of a substance from a plurality of nozzles, said nozzles being controlled in relation to the position of the nozzles relative to the substrate. In this case, the placement of the dots may be controlled very accurately.

The invention also relates to an apparatus for arranging a plurality of light-emitting diodes on a substrate comprising a printing head with a nozzle array for simultaneous deposition of a plurality of dots of a substance on the substrate to form a plurality of light-emitting pixels of the same color and means for scanning the nozzle array in at least one direction relative to the substrate. In this case, the same advantages may be achieved as discussed in relation to the corresponding method discussed above.

In a first group of embodiments, the apparatus is adapted to print a display screen comprising light-emitting diodes arranged in lines, wherein the scanning means are adapted to scan the nozzle array essentially parallel to said lines on the substrate. These embodiments provide very fast and efficient production.

In a second group of embodiments, the apparatus is adapted to print a display screen comprising light-emitting diodes arranged in lines, wherein the scanning means are adapted to scan the nozzle array essentially perpendicular to said lines on the substrate. These embodiments provide a very redundant production and generate products of very high precision.

Preferably, the angle between the length direction of the nozzle array and the scanning direction is controllable. In this case, the apparatus could be easily adapted to suit different writing operations and writing conditions.

The further scope of the applicability of the present invention will become apparent from the detailed description given hereinafter. However, it should be understood that the detailed description and specific examples, while indicating preferred embodiments of the invention, are given by way of illustration only, because various changes and modifications within the spirit and scope of the invention are apparent to those skilled in the art from this detailed description.

The invention will be described in closer detail in the following with reference to embodiments thereof illustrated in the attached drawings, wherein:

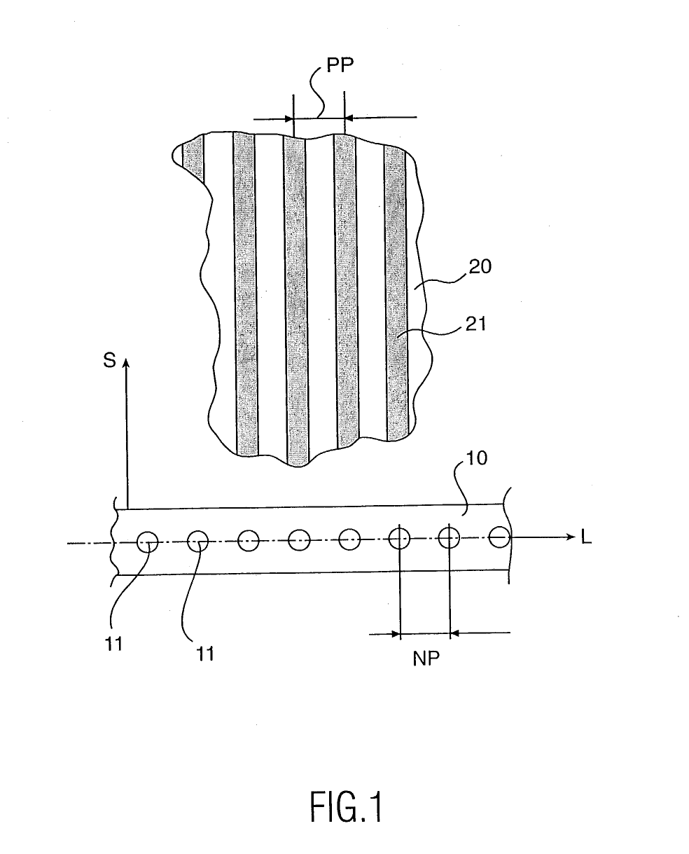

FIG. 1 is a schematic illustration of a first embodiment of the invention, where printing of a display is performed with a linear array print head, the pitch of which is equal to the pitch of the display;

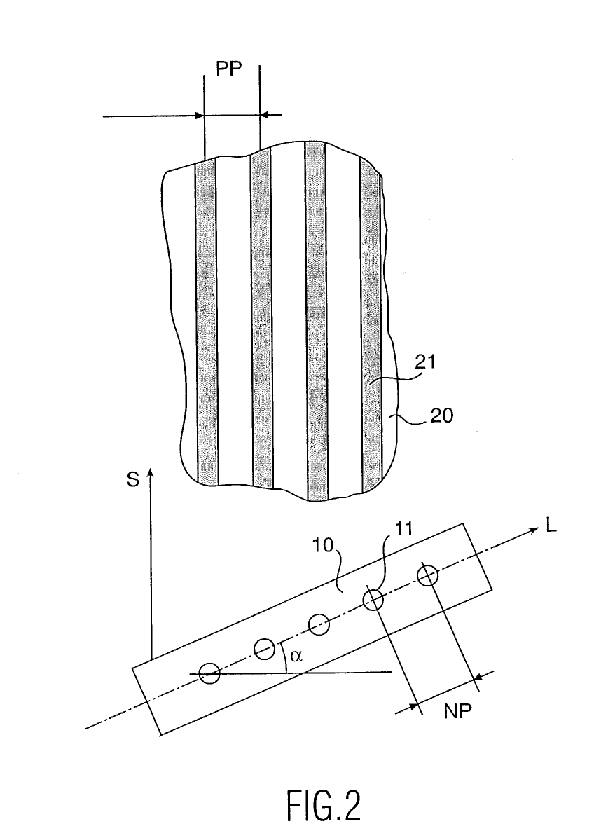

FIG. 2 is a schematic illustration of a second embodiment of the invention, where printing of a display is performed with a linear array print head, the pitch of which is not equal to the pitch of the display, and where the print head is scanned essentially parallel to the lines on the substrate;

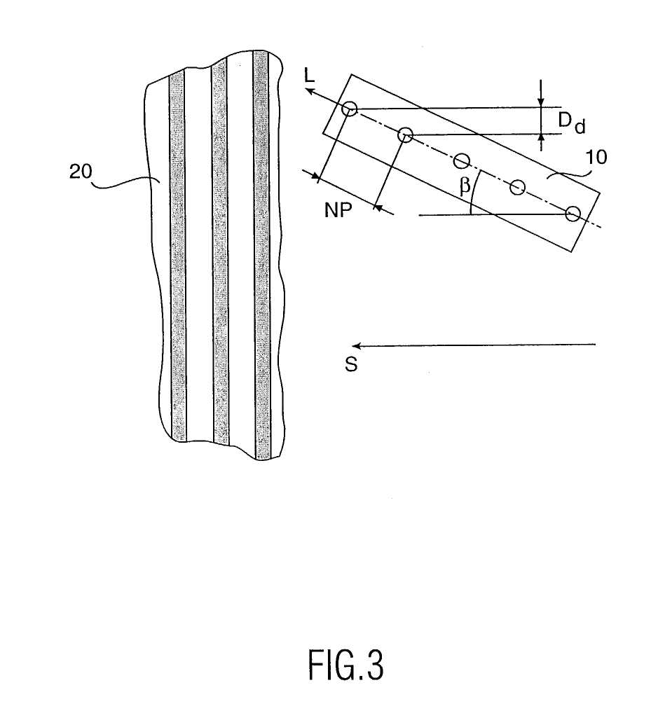

FIG. 3 is a schematic illustration of a third embodiment of the invention, where printing of a display is performed with a linear array print head, the pitch of which is not equal to the pitch of the display, and where the print head is scanned essentially perpendicular to the lines on the substrate; and

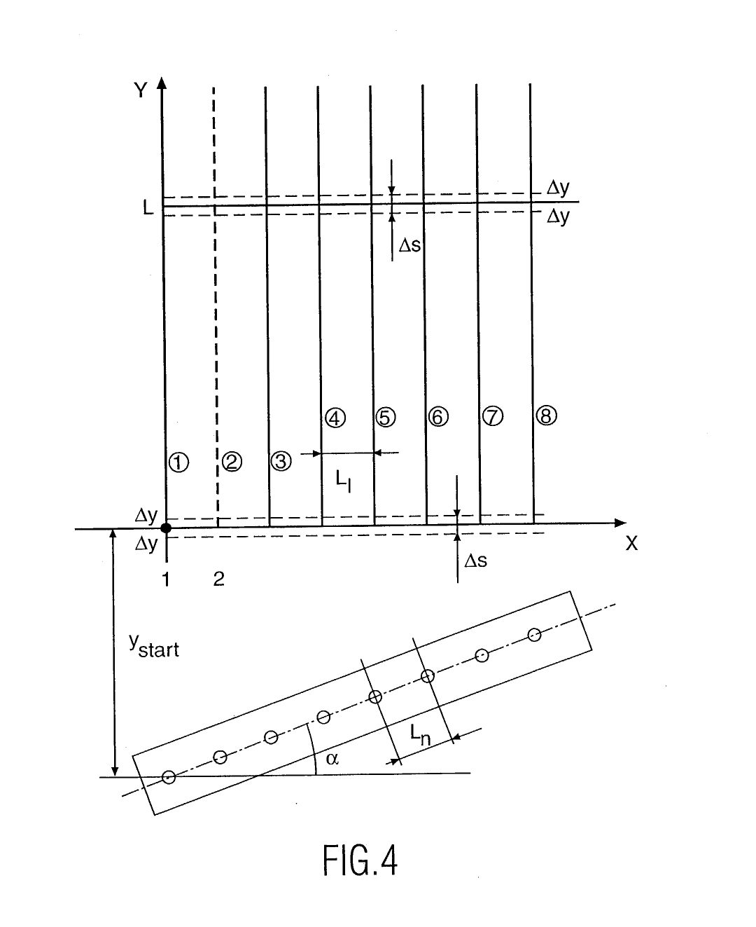

FIG. 4 is a schematic illustration of an embodiment of the invention essentially corresponding to the second embodiment; and

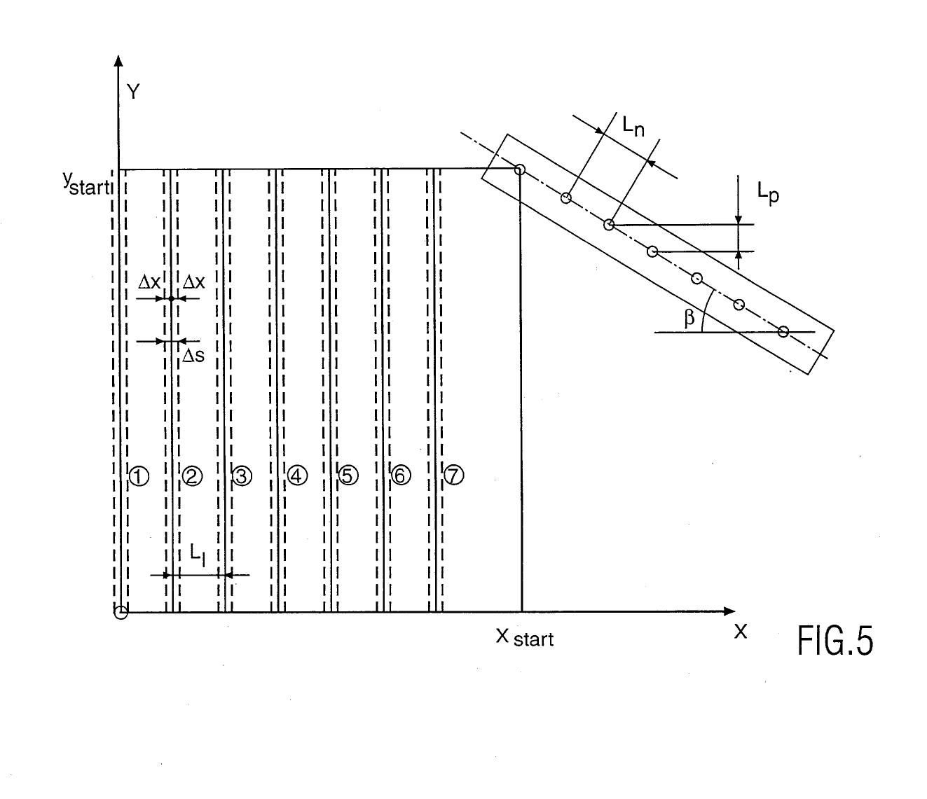

FIG. 5 is a schematic illustration of an embodiment of the invention essentially corresponding to the third embodiment.

The invention relates to a method and an apparatus for forming a plurality of light-emitting diodes (LED) on a substrate, and preferably for forming displays comprising a plurality of LEDs, referred to as polyLED display screens.

Preferably ink-jet printing is used for direct deposition of LED material, such as luminescent polymers. For such ink-jet printing, conventional ink-jet printers could be used, but modified as defined in the following. In the ink-jet printers, the ink cartridges are then replaced with polymer solutions or the like. A printer head in the printer could comprise discharge control elements, preferably of a piezoelectric material. Thus, when the printer head scans the substrate, the piezoelectric elements are pulsed, whereby discharge material is squirted from the nozzles onto the substrate.

Preferably, polymer solutions are used to make two layers on the substrate; one material layer which generates holes, and which recombine under the generation of light in the second layer.

In general terms the writing apparatus could be arranged as a conventional flat bed printer. In one embodiment, the substrate could be mounted on a X-Y table and the head could be stationary. In another embodiment, the substrate could be mounted on a linear sledge and the head on another sledge that moves at right angles with respect to the substrate sledge.

The apparatus according to the invention has a printing head with a nozzle array for simultaneous deposition of a plurality of dots of a substance on the substrate to form a plurality of light-emitting pixels of the same color. Furthermore, it comprises a device for scanning the nozzle array in at least one direction relative to the substrate.

A multi-nozzle print head could be thought of as a duplication of the single nozzle technology just as many times as needed, e.g. in order to make a display in one printing run. This way of printing displays could be referred to as the “Multi-Single Nozzle Method”. So, instead of printing lines one by one by a single nozzle print head, a multi-nozzle print head allows printing of a number of parallel lines at the same time. It is normally an advantage when the multi-nozzle print head has nozzles arranged along a straight line, a so-called linear array head, but other ways of arranging the nozzles in the print head are possible as well.

According to a first group of embodiments, the print head is scanned in a scanning direction which is essentially parallel to the lines to be written on the substrate.

According to a first embodiment, the print head 10 comprises nozzles 11 arranged at a pitch NP matching the pitch PP between lines 21 on the substrate 20 of the display to be printed, as is illustrated schematically in FIG. 1. In this case, the number of nozzles 11 is preferably equal to either the number of vertical lines or the number of horizontal lines of the display. In use, the print head is preferably arranged in parallel with either the vertical or the horizontal axis of the display, and scanned in a direction S perpendicular to the length direction L of the print head. All nozzles could then start emitting droplets at the same time and stop at the same time. In order to reach the tight tolerance on layer thickness, all nozzles should preferably produce droplets of the same volume. Thus, in the first embodiment, the apparatus is adapted to print a display screen comprising light-emitting diodes arranged in lines, wherein the scanning means are adapted to scan the nozzle array essentially parallel to said lines on the substrate, and wherein the nozzle array is arranged so that the distance between adjacent nozzles in a direction perpendicular to the scanning direction essentially corresponds to the intended distance (pitch) between adjacent dots on the substrate to be written perpendicularly to the scanning direction.

In a second embodiment, we consider the more general case where the nozzle pitch of the print head, and preferably a linear array head, does not comply with the pitch of the display. This is solved by mounting the head at an angle with respect to the axis of the display, as is illustrated in FIG. 2.

The angle α, at which the linear array print head should be adjusted with respect to the main direction on the display, is given by:

$$cos α = \frac{\text{pixel pitch display}}{n * \text{pixel linear array print head}}$$

When the pitch of the linear array print head is larger than the pitch of the display n=1. Otherwise we have to choose n>1 such that cos α<1. In the latter case, not all nozzles will be used. In this embodiment it is preferred that the nozzles of the print head are individually controllable. When starting to print the display, the nozzles could be controlled to start discharge sequentially, i.e. first the first nozzle of the linear array print head starts, a small moment of time later the second nozzle starts, then the third joins in and so on until the moment when all nozzles are operative. At the end of the lines, the reverse control scheme is used, i.e. the first nozzle reaches the end of the display first and is shut off, then the second, third and so on until the display is completely printed.

In order to print accurately and to end up with a homogeneous layer, each nozzle of the print head should preferably be able to produce droplets of constant volume regardless of the operating state of the neighboring nozzles. In other words, print heads with virtually no cross-talk between the nozzles are preferred.

Regardless of whether the pitch of the print head matches the pitch on the display or not, the droplet volume should preferably be constant, right at the start. It is further preferred that all nozzles are working at the moment they have to. Otherwise a complete line is not printed and the display will be useless in many cases.

In a second group of embodiments, the print head is scanned in a scanning direction which is essentially perpendicular to the lines to be written on the substrate.

Accordingly, in such an embodiment, the print head 10 could be arranged at an angle β such that the vertical distance between two adjacent nozzles is just equal to the distance between two adjacent dots on a line of the display. This third embodiment is schematically illustrated in FIG. 3.

The angle β is given by:

$$sin β = \frac{\text{distance between two adjacent dots}}{\text{pitch linear array print head}}$$

By running the substrate under the head perpendicular to the lines to be printed, each line will be made by placing droplets next to each other coming from nozzles next to each other. If the head has N nozzles, the head discharges over a distance N times the distance between dots, and continues by further extending the lines. In this way, the lines are built up of droplets coming from all the nozzles. In this way, differences between nozzles are averaged out. The redundancy of the printing operation is thereby increased significantly. If the distances between the droplets are much less than the dot size, one or a few nozzles may even fail without damaging the display.

It is also possible to use interlacing, in which case the angle β is chosen to be equal to:

$$sin β = \frac{n * \text{distance between two adjacent dots}}{\text{pitch linear array print head}}$$

When n=1 we have the situation already described.

When n=2, the printer starts printing lines, the next run the substrate moves over a distance equal to the distance between the adjacent drops in the direction of the lines to be printed and places droplets between the already placed drops. Then the head moves over a distance equal to (N+1) times the distance between the drops, and the procedure is repeated until the display is ready. In principle, n may be equal to N. The actual value of n is preferably chosen in dependence on the spreading and drying characteristics of the ink, etc. The method according to this embodiment also provides the possibility to enhance the accuracy in the droplet placing dependent on the position of the nozzles by tuning the firing instant of each nozzle separately.

It could easily be appreciated that when we use a multi-nozzle print head with a number of nozzles equal to the number of lines on the display that moves at right angles with respect to the direction of the lines across the substrate, the printing time is just equal to the time of printing one line with the single nozzle print head.

The situation becomes more complicated when we use a linear array print head, the nozzle pitch of which does not comply with the line pitch on the display, as is the case in the second embodiment discussed above. To explain what happens, we refer to FIG. 4.

To illustrate the invention, we could review line printing with a single nozzle print head.

The following denominations will be used:

V_{d}: volume droplet,

B: width of track to be printed,

H: ultimate thickness of layer (after evaporation of the solvent),

c: percentage of polymer in solvent,

L_{d}: dot pitch measured along line,

L: total track length,

tₚ: printing time,

vₚ: printing velocity,

f: droplet frequency.

The substrate, preferably arranged on a substrate table, is moved, and preferably at an essentially constant speed. Starting at the first dot to be placed, the table generates a pulse that triggers the print head to produce a droplet. The pulse is called the encoder signal. At the end of the line, the print head stops jetting droplets.

There is a strict relation between the encoder signal, related to L_{d}, the jetting frequency of the print head and the table speed vₚ according to:

Dot pitch measured along line:

$${L}_{d} = \frac{c {V}_{d}}{B H}$$

Printing velocity (table speed):

$${v}_{d} = \frac{{L}_{d}}{1 / f} \qquad {v}_{p} = f \frac{c {V}_{d}}{B H}$$

Print time per line:

$${t}_{p} = \frac{L}{{v}_{d}} = \frac{B L H}{c {V}_{d} f}$$

We define a co-ordinate system OXY, the OX axis is along the first row of dots, the OY axis is along the first line to be printed. The line pitch is denoted by L₁, the nozzle pitch by Lₙ. In the case discussed here, the nozzle pitch is larger than the line pitch. The number of nozzles is equal to the number of lines.

The encoder signals are produced after each scanning displacement Δs in Y-direction. The dot placement error at the beginning of the line and at the end of the line is denoted by Δy.

The encoder step length equal to the dot pitch along the lines to be printed L_{d} is coupled to the fire frequency of the print head through:

$$Δ s = {L}_{d} = \frac{{v}_{p}}{f}$$

The dot placement error Δy is half the encoder step length.

A control method of controlling the print head could be realized in software or hardware. For example, a control program for the operation of the print head could comprise the following steps:

Defining, based on the known angle, a start position of each nozzle with respect to the substrate such that the last nozzle starts discharging just above the beginning of the last line:

for i:=1 to nlines do xnozzle[i]:=(i=1)*Lnozzle cos α;

for i:=1 to nlines do ynozzle[i]:=−(nlines−1)*Lnozzle sin α+(i−1)*Lnozzle sin α;

During scanning increment in the y-direction, check whether nozzles are above positions of the substrate that should be covered, and if so discharge droplets:

repeat

for i:=1 to nlines do

begin

if (ynozzle[i]>−Δy) and (ynozzle[i]<L+Δy)

then FIRE DROPLET

end;

for i:=1 to nlines do ynozzle[i]:=

ynozzle[i]+Δs;

until ynozzle[1]>L+Δy;

The starting and end positions can be off by a distance Δy. It should be mentioned that the total printing time increases as compared with the first discussed example, because the head has to travel over a distance which is equal to the length of the line and twice the projected length of the print head on the y-axis. The command FIRE DROPLET can mean that the selected nozzle is stored and, at the very moment all lines are scanned in one addressing routine, all the selected nozzles discharge at the same time.

Normally, it is intended to end up with lines having an equal layer thickness. This could be accomplished when all nozzles produce droplets of equal volume, if we assume that the width of the lines on the substrate is uniform.

In reality a print head is not ideal and shows variations in droplet volume when going from one nozzle to another. Per nozzle the droplet volume may change due to cross-talk and drive frequency. Accordingly, compensation may be introduced to alleviate this problem.

We first consider the case where each nozzle produces a droplet volume that may deviate from that of other nozzles. Nozzle number i produces a droplet with volume V_{d,i}. Nozzle number i makes line number i. The dot pitch on line i should be:

$${L}_{d , i} = \frac{c {V}_{d , i}}{B H}$$

As the head moves at constant speed as a rigid body, because of the volume variations, each nozzle discharges droplets with a different frequency. Furthermore, we define an encoder step Δs that is considerably smaller than the smallest dot pitch.

A control method of compensating the droplet volume differences could then comprise the following steps:

Define the start position of the nozzle with respect to the substrate such that the last nozzle is just above the beginning of the last line when about to start:

for i:=1 to nlines do xnozzle[i]:=(i−1)*Lnozzle cos α;

for i:=1 to nlines do ynozzle[i]:=−(nlines−1)*Lnozzle sin α+(i−1)*Lnozzle sin α;

for i:=1 to nlines do Ld[i]:=c*Vd[i]/B/H;

for i:=1 to nlines do N[i]:=0;

During the scanning increment in the y-direction, check whether nozzles are above positions of substrate that should be covered, and if so discharge droplets, wherein the frequency of each nozzle is set in relation to the droplet volume of the nozzles:

repeat

for i:=1 to nlines do

begin

if (ynozzle[i]>−Δs) and (ynozzle[i]<L+Δs)

then begin

if (ynozzle[i]>N[i]*Ld[i]−Δs)

and (ynozzle[i]<N[i]*Ld[i]+Δs) then

begin FIRE DROPLET;N[i]:=N[i]+1;end;

end;

end; for i:=1 to nlines do ynozzle[i]:=

ynozzle[i]+Δs;

until ynozzle(1]>L+Δs;

Accordingly, the starting and end positions can be off by a distance Δs. The head has to travel over a distance which is equal to the length of the line and twice the projected length of the print head on the y-axis. The command FIRE DROPLET can mean that the selected nozzle is stored and at the very moment all lines are scanned, all the selected nozzles discharge at the same time in one addressing routine. The scanning frequency is much higher than the actual droplet frequency per nozzle. The nozzle that produce small droplets fire at a higher rate than the nozzles with larger droplets, whereby the volume deviations are compensated.

The case where the scanning direction is essentially perpendicular to the direction of the lines to be written should now be discussed. This is schematically illustrated in FIG. 5. We start by defining a co-ordinate system OXY in the same way as we did in the example above.

In this case, the dot pitch along the lines to be printed is given by:

L_{d}=Lₙ sin β

The encoder step Δs is given by the table speed divided by the droplet frequency:

$$Δ s = \frac{{v}_{p}}{f}$$

Note that in this case the dot pitch L_{d} is uncoupled from the encoder step length Δs. For the case considered, the head moves in the negative x-direction. Per step we check which nozzles are above a line. As the encoder step length is finite, it is preferred to define a tolerance area around a line in order to know whether a nozzle is above a line or not. The tolerance area is preferably given by Δx, where Δx is half of Δs.

A control method could in this case comprise the following steps:

The x-positions of the lines on the display are defined:

for i:=1 to nlines do xline[i]:=(i−1)*Lline;

The x-positions of the nozzles at the moment the first nozzle is just above the last line are identified:

xstart:=xline[nlines];

for i:=1 to nnozzles do xnozzle[i]:=xstart+(i−1)*Ln*cos(beta);

During the scanning increment in the x-direction, check whether a nozzle is above a line, and discharge droplets accordingly:

repeat

for i:=1 to nnozzles do

begin

for j:=1 to nlines do

begin

if abs(xnozzle[i]−xline[j])<Δx then FIRE DROPLET

end;

end;

for i:=1 to nnozzles do xnozzle[i]:=xnozzle[i]−Δs;

until xnozzle[nnozzles]<−Δx;

Up to now it has been assumed that the droplet landing position is equal to the nozzle position. In general, a droplet leaves the nozzle with a small deviation from straightness. Usually, this error is about 1°. When the substrate is at a 1 mm distance from the nozzle front, the dot placement error is roughly 18 μm. Instead of using the nozzle position, the dot landing position for the calculation of the x-position of the nozzles could be used. In that case, we can correct for systematic dot placement errors.

The invention has been described by way of embodiments thereof. However, several alternatives and modifications are possible. For example, by controlling the nozzles independently, the paths and directions used to scan the print head over the substrate could be chosen arbitrarily. The angle between the length direction of the nozzle array and the scanning direction is preferably controllable, whereby it could be set properly for each scanning operation. Furthermore, the scanning motion could be accomplished by moving the print head while keeping the substrate in a fixed condition, by moving the substrate while keeping the print head fixed, or by moving both the substrate and the print head, either simultaneously or in a sequential fashion. Moreover, other control methods than the ones specified above could be used. Any number of nozzles may be used in the nozzle array, but preferably the number is essentially equal to either the number of vertical lines or the number of horizontal lines to be written on the substrate. If different materials should be deposited on the substrate, e.g. for producing color displays, different nozzles on the same print head may be assigned to discharge different materials. However, it is also possible to deposit different materials in different writing runs, or to use different print heads for the different materials.

These and other modifications obvious to a person skilled in the art should be considered to be a part of this invention as defined in the appended claims.

1. A method of forming a plurality of light-emitting diodes on a substrate, the method comprising the steps of:
simultaneously depositing a plurality of dots on the substrate to form light-emitting pixels of the same color; and
repeating said depositing step in at least one displaced position on the substrate.

2. The method according to claim 1, wherein at least five dots are deposited simultaneously on the substrate to form light-emitting pixels of the same color, preferably at least 10, and most preferably at least 100.

3. The method according to claim 1 or 2, wherein the deposition is performed by a controlled discharge of a substance from a plurality of nozzles, said nozzles being controlled in relation to the position of the nozzles relative to the substrate.

4. The method according to claim 3, further comprising the step of defining a starting position on the substrate for each nozzle, wherein each nozzle is controlled to start discharging when passing said starting position during a repeated scanning displacement.

5. The method according to any one of the preceding claims, wherein said deposition comprises deposition of an organic material to form organic light-emitting diodes (OLED).

6. The method according to any one of the preceding claims, further comprising the step of depositing dots to form light-emitting pixels of at least one other color on the substrate.

7. An apparatus for arranging a plurality of light-emitting diodes on a substrate (20) comprising a printing head (10) with a nozzle array (11) for simultaneous deposition of a plurality of dots of a substance on the substrate to form a plurality of light-emitting pixels of the same color and means for scanning the nozzle array (11) in at least one direction relative to the substrate (20).

8. The apparatus to print a display screen comprising light-emitting diodes arranged in lines (21) according to claim 7, wherein the scanning means are adapted to scan the nozzle array essentially parallel to said lines on the substrate.

9. The apparatus to print a display screen comprising light-emitting diodes arranged in lines according to claim 7, wherein the scanning means are adapted to scan the nozzle array (11) essentially perpendicular to said lines on the substrate.

10. The apparatus according to any one of claims 7 to 9, wherein the nozzle array comprises a plurality of nozzles (11) displaced in a length direction (L), wherein said length direction is arranged non-parallel relative to the scanning direction (S).

11. The apparatus according to claim 10, wherein the nozzles of the nozzle array are arranged essentially along a straight line.

12. The apparatus according to claim 10 or 11, wherein the nozzle array is arranged so that the distance between adjacent nozzles (11) in a direction perpendicular to the scanning direction (S) essentially corresponds to the intended pitch/distance between adjacent dots on the substrate to be written perpendicular to the scanning direction.

13. The apparatus according to any one of claims 9 to 11, wherein the angle between the length direction of the nozzle array and the scanning direction is controllable.

14. The apparatus according to any one of claims 7 to 13, wherein the number of nozzles in the nozzle array is essentially equal to either the number of vertical lines or the number of horizontal lines to be written on the substrate.

15. An apparatus according to any one of claims 7 to 14, wherein the printing head further comprises a nozzle array for deposition of dots of at least one other substance on the substrate to form light-emitting pixels of at least one other color.

16. An apparatus according to any one of claims 7 to 15, wherein the apparatus is an ink-jet printer.
